(19) United States
(12) Patent Application Publication
(10) Pub. No.: US 2020/0372317 A1
(43) Pub. Date: Nov. 26, 2020

(54) WIRELESS COMMUNICATION SEMICONDUCTOR DEVICE AND MANUFACTURING METHOD THEREFOR

(71) Applicant: Panasonic Intellectual Property Management Co., Ltd., Osaka (JP)

(72) Inventors: KOJI OBATA, Osaka (JP); HIDEYUKI ARAI, Osaka (JP); JUN'ICHI NAKA, Osaka (JP)

(21) Appl. No.: 16/769,652

(22) PCT Filed: Jan. 23, 2019
(86) PCT No.: PCT/JP2019/001946

§ 371 Date: Jun. 4, 2020

(30) Foreign Application Priority Data
Feb. 13, 2018 (JP) 2018-023038

(51) Int. Cl. G06K 19/077; H01L 21/822; H01L 29/786

(52) U.S. Cl. CPC G06K 19/07773; H01L 29/786; H01L 21/822

(57) ABSTRACT

A wireless communication semiconductor device includes a circuit board, a semiconductor chip mounted on the circuit board, a thin film transistor provided on the circuit board, and an antenna provided on the circuit board. Even if a different unique ID is assigned to each of the wireless communication semiconductor devices, as compared with silicon-based wireless communication semiconductor devices, a manufacturing cost per device is sufficiently reduced, and the reduction in operation speed and reliability is sufficiently prevented.

### TECHNICAL FIELD

The present disclosure relates to a wireless communication semiconductor device such as a radio frequency identification (RFID) tag and an integrated circuit (IC) tag that receives a radio wave from an external reader device and returns the radio wave based on unique identification (ID) information to the external reader device, and a manufacturing method therefor.

The present disclosure particularly relates to a wireless communication semiconductor device such as an RFID tag and an IC tag that receives driving power from an external reader device and returns unique ID information to the external reader device, and a manufacturing method therefor.

### BACKGROUND ART

Even if wireless communication semiconductor devices, such as RFID tags and an IC tags, are located far from an external reader device, the external reader device can read information on the wireless communication semiconductor devices collectively simply by holding the external reader device over the wireless communication semiconductor devices as long as the wireless communication semiconductor device is located in an area (for example, several millimeters to several tens of meters) where radio waves from the external reader device can reach. Therefore, the wireless communication semiconductor device is extremely useful for distribution management (logistics management), production management, inventory management, location management, history management, and the like in the retail industry such as convenience stores and supermarkets, the apparel industry, the transportation industry, and the publishing industry (libraries).

A wireless communication semiconductor device typically includes an antenna and an IC chip. An IC chip typically includes a radio circuit unit that processes a reception wave received by an antenna, a memory unit that stores a reception signal and the like in the radio circuit unit, a power supply circuit unit that generates driving power, and a control circuit unit that stores a reception signal in the memory unit, and the like (PTLs 1 and 2).

A wireless communication semiconductor device in which a thin film transistor is included in each of a radio circuit unit, a memory unit, a power supply circuit unit, and a control circuit unit has been reported (Imec Belgian, Holst Center (a research and development institute jointly operated by the Netherlands Organization for applied scientific research (TNO) and Imec Belgian) and Cartamundi, Feb. 5-9, 2017, San Francisco, USA, “International Solid-State Circuits Conference 2017 (ISSCC 2017)”).

### CITATION LIST

### Patent Literature

PTL 1: Japanese Patent No. 4761779

PTL 2: Japanese Patent Laid-Open Publication No. 2006-24087

### SUMMARY

A wireless communication device according to the present disclosure includes: a circuit board; a semiconductor chip mounted on the circuit board; a thin film transistor that is provided on the circuit board; and an antenna that is provided on the circuit board.

A method for manufacturing a wireless communication device according to the present disclosure includes: mounting a semiconductor chip on a circuit board; and forming a thin film transistor, an antenna, and a wiring on the circuit board by printing.

Even if a different unique ID is assigned to each of the wireless communication devices of the present disclosure, as compared to silicon-based wireless communication devices, a manufacturing cost per device is sufficiently reduced, and a decrease in reliability with respect to operation speed and operation stability is sufficiently prevented.

### BRIEF DESCRIPTION OF DRAWINGS

FIG. 1 is a schematic conceptual view of an example of a structure of a wireless communication device according to Embodiment A of the present disclosure.

FIG. 2 is a schematic plan view of another example of the wireless communication device according to Embodiment A of the present disclosure.

FIG. 3 is a block view of an example of a circuit configuration of the wireless communication device according to Embodiment A of the present disclosure.

FIG. 4A is a schematic circuit diagram illustrating an arrangement of radio circuit unit RF, memory unit ME (ME1 and ME2), power supply circuit unit PW, and control circuit unit LO (LO1 and LO2) in the circuit configuration of a wireless communication device according to Embodiment 1 included in Embodiment A of the present disclosure.

FIG. 4B is a schematic circuit diagram illustrating an arrangement of radio circuit unit RF, memory unit ME (ME1 and ME2), power supply circuit unit PW, and control circuit unit LO (LO1 and LO2) in the circuit configuration of a wireless communication device according to Embodiment 2 included in Embodiment A of the present disclosure.

FIG. 4C is a schematic circuit diagram illustrating an arrangement of radio circuit unit RF, memory unit ME (ME1 and ME2), power supply circuit unit PW, and control circuit unit LO (LO1 and LO2) in the circuit configuration of a wireless communication device according to Embodiment 3 included in Embodiment A of the present disclosure.

FIG. 5A is a schematic view illustrating a step of preparing a support board in a method for manufacturing the wireless communication device according to Embodiment A of the present disclosure.

FIG. 5B is a schematic view illustrating a step of manufacturing a circuit board in the method for manufacturing the wireless communication device according to Embodiment A of the present disclosure.

FIG. 5C is a schematic view illustrating a step of forming a gate electrode in the method for manufacturing the wireless communication device according to Embodiment A of the present disclosure.

FIG. 5D is a schematic view illustrating a step of forming an insulating layer in the method for manufacturing the wireless communication device according to Embodiment A of the present disclosure.

FIG. 5E is a schematic view illustrating a step of forming a semiconductor layer in the method for manufacturing the wireless communication device according to Embodiment A of the present disclosure.

FIG. 5F is a schematic view illustrating a step of forming a source electrode and a drain electrode in the method for manufacturing the wireless communication device according to Embodiment A of the present disclosure.

FIG. 5G is a schematic view illustrating a step of mounting a semiconductor chip in the method for manufacturing the wireless communication device according to Embodiment A of the present disclosure.

FIG. 5H is a schematic view illustrating a step of forming an antenna and a wiring in the method for manufacturing the wireless communication device according to Embodiment A of the present disclosure.

FIG. 5I is a schematic view illustrating a step of forming a protection layer in the method for manufacturing the wireless communication device according to Embodiment A of the present disclosure.

FIG. 5J is a schematic view illustrating a step of peeling off the support board in the method for manufacturing a wireless communication device according to Embodiment A of the present disclosure.

FIG. 6A is a schematic cross-sectional view illustrating a step of preparing the support board in the method for manufacturing the wireless communication device according to Embodiment A of the present disclosure.

FIG. 6B is a schematic cross-sectional view illustrating a step of manufacturing the circuit board in the method for manufacturing the wireless communication device according to Embodiment A of the present disclosure.

FIG. 6C is a schematic cross-sectional view illustrating a step of forming the gate electrode in the method for manufacturing the wireless communication device according to Embodiment A of the present disclosure.

FIG. 6D is a schematic cross-sectional view illustrating a step of forming the insulating layer in the method for manufacturing the wireless communication device according to Embodiment A of the present disclosure.

FIG. 6E is a schematic cross-sectional view illustrating a step of forming the semiconductor layer in the method for manufacturing the wireless communication device according to Embodiment A of the present disclosure.

FIG. 6F is a schematic cross-sectional view illustrating a step of forming the source electrode and the drain electrode in the method for manufacturing the wireless communication device according to Embodiment A of the present disclosure.

FIG. 6G is a schematic cross-sectional view illustrating a step of mounting the semiconductor chip in the method for manufacturing the wireless communication device according to Embodiment A of the present disclosure.

FIG. 6H is a schematic cross-sectional view illustrating a step of forming the antenna and the wiring in the method for manufacturing the wireless communication device according to Embodiment A of the present disclosure.

FIG. 6I is a schematic cross-sectional view illustrating a step of forming the protection layer in the method for manufacturing the wireless communication device according to Embodiment A of the present disclosure.

FIG. 6J is a schematic cross-sectional view illustrating a step of peeling off the support board in the method for manufacturing the wireless communication device according to Embodiment A of the present disclosure.

FIG. 7A is a schematic cross-sectional view of a wireless communication device according to Embodiment b1 included in Embodiment B of the present disclosure.

FIG. 7B is a schematic cross-sectional view of the wireless communication device of FIG. 7A in which more sufficient additional writing is possible.

FIG. 8A is a schematic cross-sectional view of a wireless communication device according to Embodiment b2 included in Embodiment B of the present disclosure.

FIG. 8B is a schematic cross-sectional view of the wireless communication device shown in FIG. 8A in which more sufficient additional writing is possible.

### DETAIL DESCRIPTION OF PREFERRED EMBODIMENTS

Wireless communication devices according to an embodiment of the present disclosure will be described below.

In a conventional wireless communication semiconductor device, a silicon chip is mounted, and a radio circuit unit, a memory unit, a power supply circuit unit, and a control circuit unit are all provided in the silicon chip. Hereinafter, such a wireless communication semiconductor device may be referred to as a “silicon-based wireless communication semiconductor device” or a “silicon-based wireless communication device”. Silicon chips can operate at a higher speed, are small, have high reliability, and are suitable for mass production. But when a different unique ID is assigned to each of the silicon-based wireless communication semiconductor devices, the manufacturing cost per wireless communication semiconductor device increases significantly.

The wireless communication semiconductor device reported at the International Solid-State Circuits Conference 2017 includes a thin film transistor instead of a silicon chip. Hereinafter, such a wireless communication semiconductor device may be referred to as a “TFT-based wireless communication semiconductor device” or a “TFT wireless communication device”. Thin film transistors (particularly, organic thin film transistors) can be manufactured by a printing method and are suitable for small-scale production, and when a different unique ID is assigned to each of the TFT-based wireless communication semiconductor devices, the manufacturing cost per wireless communication semiconductor device can be reduced. However, a thin film transistor (particularly, an organic thin film transistor) has a lower operation speed (that is, a lower operation frequency) and lower reliability regarding operation stability than a silicon chip. Therefore, the reliability of the TFT-based wireless communication semiconductor device with respect to the operation speed (that is, the operation frequency) and the operation stability is significantly lower than that of the silicon-based wireless communication semiconductor device. For example, a TFT-based wireless communication semiconductor device cannot achieve a desired operation speed (for example, an operation frequency of 920 MHz) in a 920 MHz band.

On the other hand, inventors of the present disclosure have found a problem in the following situation. Attempts have been made to provide a single wireless communication semiconductor device with various unique IDs or information linked to the unique IDs in various scenes each time. In such attempts, for example, by attaching a wireless communication semiconductor device to a rental item such as a bicycle and assigning information such as the name and address of a borrower of the rental item to the wireless communication semiconductor device as a unique ID or information linked to the unique ID in each scene, it is possible to promote to return. Also, for example, by attaching a wireless communication semiconductor device to livestock such as cows and pigs and assigning information such as the position information and the owner of the livestock to the wireless communication semiconductor device as a unique ID or information linked to the unique ID in each scene such as delivery, breeding, and the like, it is possible to guarantee the producer and brand of each livestock individual. However, the inventors of the present disclosure have found that silicon-based wireless communication semiconductor devices have security-related problems such as fake and forgery. Specifically, in a silicon-based wireless communication semiconductor device, a memory unit is provided on a silicon chip, a unique ID and information linked to the unique ID need to be stored in a rewritable area in the silicon chip, each time the rewritable area can be rewritten, and therefore security-related problems such as fake and forgery have occurred. Hereinafter, in the present specification and claims, a unique ID or information linked to the unique ID may be referred to as unique ID-related information.

Even if different unique IDs are assigned to each of the wireless communication semiconductor devices, the present disclosure provides a wireless communication semiconductor device and a method for manufacturing the same that is capable of more sufficiently reducing a manufacturing cost per device than silicon-based wireless communication semiconductor devices and is capable of suppressing a decrease from silicon-based wireless communication semiconductor devices in reliability related to operation speed and operation stability.

Even if a different unique ID is assigned to each of the wireless communication semiconductor devices, the present disclosure further provides a wireless communication semiconductor device and a method for manufacturing the same that is capable of not only more sufficiently reducing a manufacturing cost per device than silicon-based wireless communication semiconductor devices, and is capable of preventing a decrease from silicon-based wireless communication semiconductor devices in reliability with respect to operation speed and operation stability, but also is capable of sufficiently preventing security-related problems, such as forgery, with a simpler structure as well as silicon-based wireless communication semiconductor devices.

In this specification, a wireless communication semiconductor device may be referred to as a “wireless communication device”.

In the present disclosure, a unique ID is unique ID information assigned to each wireless communication device (for example, an RFID tag). Specific examples of additional information that can be linked to such a unique ID include, for example, the following information:
Individual number, birth place, breeding place, and owner history of livestock when a wireless communication device is attached to livestock;
Sharing history when a wireless communication device is attached to an object in the sharing economy (type of object, borrower and time of object);
Traceability (for example, history of distribution channels from the production stage to the consumption or disposal stage) of an article (for example, food) to which the wireless communication device is attached;
Owner history of expensive artwork; and
Temperature history of an article (for example, food) to which the wireless communication device is attached

Additional information that can be linked to such a unique ID may be stored in a rewritable memory of a wireless communication device (for example, an RFID tag), may be managed on cloud to be linked to the unique ID, or may be stored in a RAM or a ROM described later. Being linked to a unique ID means being stored or managed in association with a unique ID.

### Wireless Communication Device According to Embodiment A

In a wireless communication device according to Embodiment A of the present disclosure, a semiconductor chip and a thin film transistor (hereinafter, referred to as “TFT”) are used in combination. That is, in the wireless communication device of the present embodiment, not all of the members such as the radio circuit unit, the memory unit, the power supply circuit unit, and the control circuit unit, which will be described in detail later, are provided in the semiconductor chip, and some of these members are provided in the TFT. Some other members are provided on the semiconductor chip. For this reason, in the wireless communication device according to the present embodiment, as compared to the silicon-based wireless communication device of the related art, the manufacturing cost per device is reduced more sufficiently, while a decrease in operation speed and reliability is more sufficiently prevented. The wireless communication device of the present embodiment can also be referred to as a “hybrid wireless communication device” in view of the combined use (use of the combination) of the semiconductor chip and the TFT.

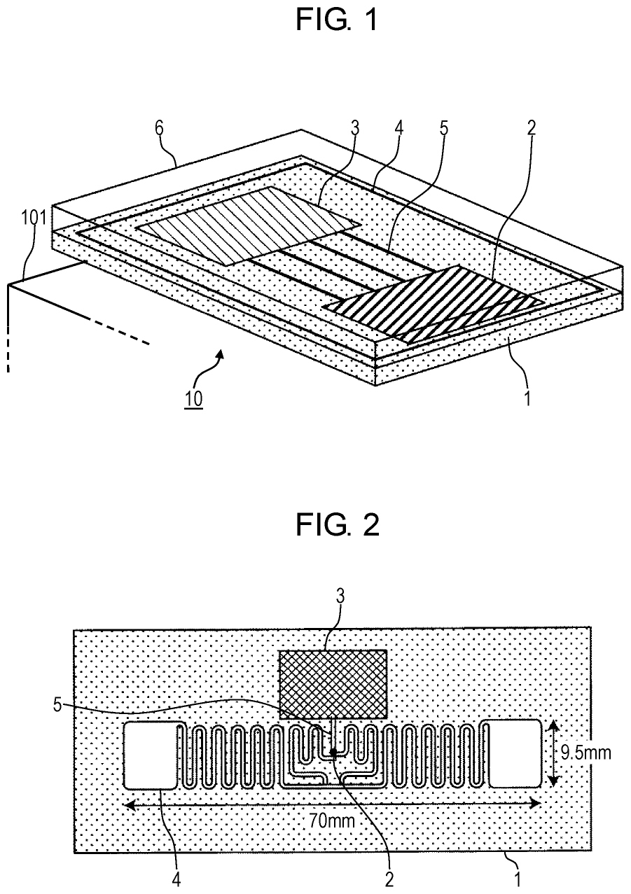

More specifically, as illustrated in FIG. 1, wireless communication device 10 of the present embodiment includes circuit board 1, semiconductor chip 2, TFT 3, and antenna 4, and may further include wiring 5 and/or protection layer 6. That is, wireless communication device 10 may further include at least one of wiring 5 and protection layer 6. FIG. 1 is a schematic view illustrating an example of the structure of the wireless communication device according to the present embodiment when protection layer 6 is transparent.

Circuit board 1 has a sheet shape or a plate shape for attaching, disposing or positioning electronic components, such as semiconductor chip 2, thereon. Circuit board 1 is not particularly limited as long as the circuit board has so-called electrical insulation, and may be, for example, a polymer board and may be an inorganic board (for example, a metal board, a glass board, or a ceramic board) having a polymer layer on a surface on which a semiconductor chip or the like is formed. In the present embodiment, circuit board 1 is a polymer board. The electrical insulation means a resistivity, for example, being equal to or more than 10⁸ Ωm, preferably ranging from 10⁸ to 10¹⁷ Ωm. The polymer forming the polymer board and the polymer layer may be, for example, at least one resin material selected from the group consisting of polyester resin (for example, polyethylene terephthalate resin), polyimide resin, polyolefin resin (for example, polyethylene resin and polypropylene resin), polyphenylene sulfide resin, polyvinyl formal resin, polyurethane resin, polyamide imide resin, polyamide resin, and the like. Preferably, polyimide resin is used as the material.

The thickness of circuit board 1 is not particularly limited, and may be appropriately determined according to the use of the wireless communication device of the present embodiment (for example, the type of the target to which the wireless communication device is attached). The thickness of circuit board 1 may be, for example, 100 μm or more, and preferably 200 μm or more. The upper limit of the thickness of circuit board 1 is not particularly limited, and the thickness is preferably 10 mm or less, more preferably, 1 mm or less.

Semiconductor chip 2 is a semiconductor element mounted on circuit board 1 and is an electronic device also called a semiconductor integrated circuit. As semiconductor chip 2, a solid-state circuit, such as a silicon chip or a compound semiconductor chip, is mainly used. The semiconductor chip is not particularly limited and can be obtained in a minimum unit on the distribution market as long as the semiconductor chip includes a member, such as a radio circuit unit, a memory unit, a power supply circuit unit, and a control circuit unit, which will be described later. One or more semiconductor chips 2 are used per wireless communication device, and one is used per wireless communication device in the present embodiment.

Semiconductor chip (particularly, a silicon chip) 2 is arranged such that the pads face upward. Here, “upward” means the semiconductor chip is mounted “upward” on the surface of the circuit board on a substantially horizontal plane. The mounting is, for example, the semiconductor chip is placed with the surface of the largest area of the semiconductor chip as the bottom.

In the present embodiment, the operation frequency of semiconductor chip 2 is higher than the operation frequency of TFT 3 described later. In this manner, it is possible to provide a wireless communication device that can operate at a higher speed and that is easy to manufacture. In the present embodiment, the operation frequency of semiconductor chip 2 ranges from 0.1 to 2450 MHz, and preferably from 860 to 2450 MHz from the viewpoint of higher-speed operation of the wireless communication device.

TFT 3 is a switch that allows electricity to flow from a source electrode to a drain electrode by controlling the potential of a gate electrode and is not particularly limited as long as the TFT is a semiconductor thin film device that can constitute members such as a radio circuit unit, a memory unit, a power supply circuit unit, and a control circuit unit, which will be described later. The TFT may be any known TFT, and may be, for example, an organic TFT in which a channel portion (layer) between a source electrode and a drain electrode is made of an organic semiconductor material or an inorganic TFT in which a channel portion (layer) is made of an inorganic semiconductor material. The organic TFT may be, for example, a polymer material (for example, polythiophene or a derivative thereof), a low-molecular material (for example, pentacene and solubilized pentacene), a nanocarbon material (for example, carbon nanotube, SiGe nanowire, fullerene, and modified fullerene), and/or an inorganic-organic mixed material (for example, a complex system of (C₆H₅C₂H₄NH₃) and SnI₄). The inorganic TFT may be, for example, a silicon TFT, such as an amorphous silicon TFT or a polycrystalline silicon TFT.

The structure of TFT (particularly, organic TFT) 3 may be any known structure, and may be, for example, a so-called bottom gate-bottom contact type, top gate-bottom contact type, bottom gate-top contact type, top gate-top contact type, or the like. From the viewpoint of further reducing the manufacturing cost and further improving the simplicity of manufacturing the TFT, the TFT is preferably a bottom gate-top contact type organic TFT.

TFT 3 is preferably a printed component from the viewpoints of further reducing the manufacturing cost, further improving the security performance with a simple structure, and further improving the simplicity of manufacturing the TFT. TFT 3 being a printed component means that TFT 3 is a component manufactured by printing which will be described later.

TFT 3 is preferably an organic TFT from the viewpoints of further reducing the manufacturing cost, further improving the security performance with a simple structure, and further improving the simplicity of manufacturing the TFT. As described later, the organic TFT can be easily manufactured with a simpler structure by a printing method (particularly, an ink jet printing method), but the security performance is further improved.

In the present embodiment, one or more TFTs 3 are used per one wireless communication device. In the case that the wireless communication device of the present embodiment includes protection layer 6 described later, all TFTs 3 may be electrically connected to semiconductor chip 2 by wirings 5 formed under protection layer 6 (that is, between circuit board 1 and protection layer 6). Alternatively, TFTs 3 may be connected to each other by wiring 5, and one or more TFTs 3 among all TFTs 3 may be connected to semiconductor chip 2 by wiring 5. For example, when TFT 3-1 is connected with TFT 3-2 and TFT 3-1 is connected with semiconductor chip 2, TFT 3-2 and semiconductor chip 2 may not be connected.

Antenna 4 is not particularly limited as long as the antenna can receive a reception wave that is a radio wave from external reader device 101 and can transmit a transmission wave that is a radio wave based on the unique ID of the wireless communication device to external reader device 101. Specifically, antenna 4 receives a reception wave and outputs a reception wave signal generated by the reception wave. Further, antenna 4 receives a transmission wave signal, generates a transmission wave based on the transmission wave signal, and transmits the transmission wave to external reader device 101. The type of antenna 4 may be determined by the frequency of the radio wave and may be, for example, a loop antenna, a spiral antenna, a dipole antenna, a patch antenna as illustrated in FIG. 1, or a folded dipole antenna as illustrated in FIG. 2. In particular, when the frequency of the radio wave is 860 to 2450 MHz, a dipole antenna is preferable. FIG. 2 is a schematic plan view illustrating an example of the wireless communication device according to the present embodiment, in which a protection layer is omitted. The plan view is a view when an object (for example, a wireless communication device) is mounted and viewed from directly above the thickness (height) direction.

The thickness of antenna 4 is not particularly limited, and may be, for example, 10 nm or more, particularly 50 nm or more, and ranges from 10 nm to 100 μm in the present embodiment.

The dimensions of antenna 4 are not particularly limited. For example, in a folded dipole antenna as illustrated in FIG. 2, in the present embodiment, the length in the longitudinal direction ranges from 10 to 200 mm, preferably from 50 to 100 mm, for example, 70 mm in one example. In the present embodiment, the length in the width direction perpendicular to the longitudinal direction is 5 to 50 mm, preferably ranges from 5 to 20 mm, and for example, is 9.5 mm.

Antenna 4 is preferably a printed component from the viewpoints of further reducing the manufacturing cost, further improving the security performance with a simple structure, and further improving the simplicity of manufacturing the antenna. Antenna 4 being a printed component means that antenna 4 is a component manufactured by printing which will be described later.

Antenna 4 is not particularly limited as long as the antenna is made of conductive material, and may be made of, for example, metal material, such as silver (Ag), copper (Cu), nickel (Ni), aluminum (Al), or stainless steel (SUS).

Wiring 5 is to electrically connect semiconductor chip 2, TFT 3 with antenna 4. Specifically, wiring 5 includes at least a wiring for electrically connecting semiconductor chip 2 with TFT 3, and may further include a wiring for electrically connecting semiconductor chip 2 with antenna 4. Wiring 5 may include a wiring for electrically connecting TFT 3 and antenna 4.

The thickness of wiring 5 is not particularly limited and may be, for example, 10 nm or more, particularly 50 nm or more, and ranges from 10 nm to 100 μm in the present embodiment.

Wiring 5 is preferably a printed component from the viewpoints of further reducing the manufacturing cost, further improving the security performance with a simple structure, and further improving the simplicity of manufacturing the wiring. Wiring 5 being a printed component means that wiring 5 is a component manufactured by printing which will be described later.

Wiring 5 is not particularly limited as long as the wiring is made of conductive material, and may be made of, for example, metal material, such as silver (Ag), copper (Cu), nickel (Ni), aluminum (Al), or stainless steel (SUS).

Protection layer 6 is formed so as to cover at least semiconductor chip 2 and the like on the side where semiconductor chip 2, TFT 3, antenna 4, and wiring 5 (hereinafter, referred to as “semiconductor chip 2 and the like”) are formed on circuit board 1 and protects and seals semiconductor chip 2 and the like. In FIG. 1, protection layer 6 is illustrated as being transparent for description of other members, but is not limited thereto and may be opaque.

The material forming protection layer 6 is not particularly limited as long as semiconductor chip 2 and the like can be protected from moisture and oxygen in the air and an external impact, and for example, an epoxy resin, a polyimide (PI) resin, an acrylic resin, a polyethylene terephthalate (PET) resin, a polyethylene naphthalate (PEN) resin, a polyphenylene sulfide (PPS) resin, a polyphenylene ether (PPE) resin, a fluorine resin, or a composite thereof can be used. Preferably, a fluorine resin is used.

The thickness of protection layer 6 is not particularly limited, and is, for example, 100 nm or more, preferably ranges from about 1 μm to about 10 μm, for example, is about 1 μm.

Protection layer 6 is preferably a printed component from the viewpoints of further reducing the manufacturing cost, further improving the security performance with a simple structure, and further improving the simplicity of manufacturing the protection layer. Protection layer 6 being a printed component means that protection layer 6 is a component manufactured by printing which will be described later.

In FIG. 1, in wireless communication device 10, semiconductor chip 2, TFT 3, antenna 4, wiring 5, and protection layer 6 are provided on only one surface of circuit board 1, but may be provided independently on both surfaces as long as semiconductor chip 2, TFT 3, antenna 4, and wiring 5 are electrically connected to each other. For example, wireless communication device 10 may include semiconductor chip 2 and protection layer 6 on one surface and TFT 3 and protection layer 6 on the other surface and connect semiconductor chip 2 and TFT 3 with via-type wiring 5. At this time, wireless communication device 10 may include antenna 4 and additional wiring 5 independently on at least one surface. A via is a via hole or through hole in semiconductor technology.

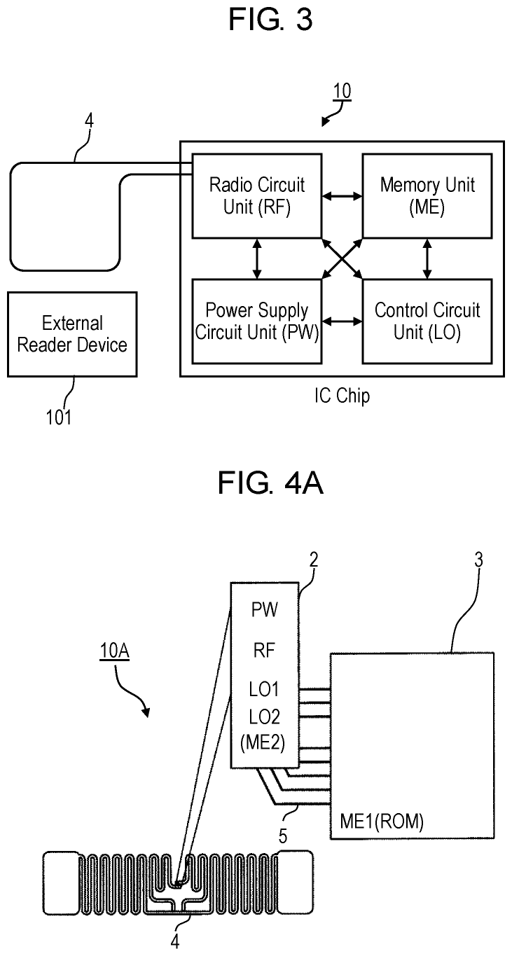

As illustrated in FIG. 3, the wireless communication device of the present embodiment includes radio circuit unit RF and memory unit ME in a circuit configuration, and preferably further includes power supply circuit unit PW and control circuit unit LO. In the present embodiment, radio circuit unit RF, memory unit ME, power supply circuit unit PW, and control circuit unit LO constitute an IC chip while being electrically connected to each other, as illustrated in FIG. 3. In the present embodiment, antenna 4 is electrically connected to radio circuit unit RF. FIG. 3 is a block diagram illustrating an example of a circuit configuration of the wireless communication device according to the present embodiment.

Radio circuit unit RF processes a reception wave signal generated by antenna 4 with a reception wave received by antenna 4 to generate a reception signal and generate a transmission wave signal for antenna 4 to transmit a transmission signal for a reply. More specifically, radio circuit unit RF includes a clock generation unit, a demodulation circuit, and a modulation circuit. The clock generation unit generates a clock signal necessary for the operation of a control circuit unit described later based on the reception wave signal. For example, a clock signal of several tens to several hundreds kHz is generated from a reception wave signal of several MHz. The demodulation circuit demodulates a reception signal (data) from the reception wave signal. The modulation circuit performs modulation for generating a transmission wave signal by carrying a transmission signal (data) to be transmitted on a carrier wave. The transmission wave signal is supplied to antenna 4, and antenna 4 generates a transmission wave based on the transmission wave signal and transmits the transmission wave to external reader device 101.

Radio circuit unit RF is provided on semiconductor chip 2 in the present embodiment. This configuration provides higher-speed operation of the wireless communication device.

Radio circuit unit RF being provided in semiconductor chip 2 means that semiconductor chip 2 or a part thereof is used as a radio circuit unit or that semiconductor chip 2 or a part thereof performs the function of a radio circuit unit.

Memory unit ME stores a unique ID. Memory unit ME may further store information linked to the unique ID. Memory unit ME may store the reception signal and/or the transmission signal in radio circuit unit RF, that is, may store at least one of the reception signal and the transmission signal. In the present embodiment, memory unit ME includes unique ID memory unit ME1 that stores a unique ID and may further include another memory unit ME2 that is configured to store information other than the unique ID (for example, a reception signal and/or a transmission signal in radio circuit unit RF, that is, at least one of the reception signal and the transmission signal). The reception signal and the transmission signal may be stored by unique ID memory unit ME1 or the other memory unit ME2. In the present embodiment, the reception signal and the transmission signal is stored by the other memory unit ME2. Memory unit ME may or may not include the other memory unit ME2.

At least a part of memory unit ME is provided in the TFT. That is, at least unique ID memory unit ME1 of memory unit ME is provided in TFT 3, and the other memory unit ME2 may be provided in semiconductor chip 2 or may be provided in TFT 3. The other memory unit ME2 may not be provided in either semiconductor chip 2 or TFT 3. This configuration sufficiently prevents security-related problems, such as fake and forgery with a simple structure. If unique ID memory unit ME1 is provided in semiconductor chip 2, the unique ID can be rewritten in various scenes each time, and thus security-related problems, such as fake and forgery occur.

Unique ID memory unit ME1 being provided in TFT 3 means that TFT 3 or a part thereof is used as unique ID memory unit ME1 or that TFT 3 or a part thereof performs the function of unique ID memory unit ME1.

The other memory unit ME2 being provided in semiconductor chip 2 means that semiconductor chip 2 or a part thereof is used as the other memory unit ME2 or that semiconductor chip 2 or a part thereof performs the function of the other memory unit ME2.

The other memory unit ME2 being provided in TFT 3 means that TFT 3 or a part thereof is used as the other memory unit ME2 or that TFT 3 or a part thereof performs the function of the other memory unit ME2.

A read only memory (ROM) is used for unique ID memory unit ME1. This configuration sufficiently prevents security-related problems such as fake and forgery with a simple structure. If a readable and writable random access memory (RAM) (volatile memory) is used for unique ID memory unit ME1, the unique ID can be rewritten in various scenes each time, and thus security-related problems such as fake and forgery occur.

For the other memory unit ME2, a read-only ROM may be used, or a readable and writable RAM may be used. Since the contents of the memory can be rewritten as needed, it is preferable to use a readable and writable RAM for the other memory unit ME2.

The other memory unit ME2 may provide a rewritable area via wireless. In this case, a RAM is used for the other memory unit ME2. The other memory unit ME2 may be provided in semiconductor chip 2, may be provided in TFT 3, or may be provided in both of semiconductor chip 2 and TFT 3.

Power supply circuit unit PW generates driving power of wireless communication device 10. Power supply circuit unit PW may be a power supply circuit unit including a battery. But from the viewpoint of a simpler wireless communication device structure, the power supply circuit unit does not preferably include a battery and generates driving power by rectifying a reception wave signal generated by a reception wave received by the antenna.

Power supply circuit unit PW preferably includes a rectifier circuit, and more preferably further includes a booster circuit. The rectifier circuit rectifies the reception wave signal and supplies a direct-current (DC) voltage to radio circuit unit RF, memory unit ME, and control circuit unit LO described later. The booster circuit boosts the electromotive force generated in the rectifier circuit to a higher voltage.

Power supply circuit unit PW is provided in semiconductor chip 2 in the present embodiment. The rectifier circuit and the booster circuit are provided in semiconductor chip 2. This configuration provides higher-speed operation of the wireless communication device.

Power supply circuit unit PW being provided in semiconductor chip 2 means that semiconductor chip 2 or a part thereof is used as power supply circuit unit PW or that semiconductor chip 2 or a part thereof performs the function of Power supply circuit unit PW.

Control circuit unit LO causes memory unit ME to store a reception signal and/or a transmission signal, that is, at least one of the reception signal and the transmission signal, the unique ID, and information linked to the unique ID as desired, and causes radio circuit unit RF to generate a reception signal and a carrier wave. That is, control circuit unit LO causes memory unit ME to store at least the unique ID and may or may not cause memory unit ME to store a reception signal and/or a transmission signal, that is, at least one of the reception signal and the transmission signal, and the information linked to the unique ID as desired. Memory unit ME causes radio circuit unit RF to generate a reception signal and a carrier wave. Control circuit unit LO includes memory control circuit unit LO1 that causes memory unit ME to store a reception signal and/or a transmission signal, that is, at least one of the reception signal and the transmission signal, a unique ID, and information linked to the unique ID as desired, and may further include another control circuit unit LO2 that causes radio circuit unit RF to generate a reception signal and a carrier wave, and to control the entire wireless semiconductor device. Memory control circuit unit LO1 does not necessarily store the information linked to the unique ID in memory unit ME. The other control circuit unit LO2 may control an operation mode of the wireless semiconductor device (for example, switching between a low power mode, a normal mode, and a non-rewritable mode).

More specifically, memory control circuit unit LO1 writes a reception signal based on a reception wave received by the antenna to the memory unit and/or reads a transmission signal transmitted by the antenna from the memory unit. That is, memory control circuit unit LO1 performs at least one of writing of the reception signal to the memory unit and reading of the transmission signal from the memory unit. From the viewpoint of further improving the reliability of wireless communication device 10, when there is a circuit for performing parity check of a reception signal (data) and/or when there are plural wireless communication devices 10, an anti-collision circuit and the like for identifying each other may be added to memory control circuit unit LO1. That is, at least one of a parity check circuit and an anti-collision circuit may be added to memory control circuit unit LO1.

The other control circuit unit LO2 may include a decoding circuit, an encoding circuit, a serial input/output (I/O), and a command processing circuit. The decoding circuit decodes the reception signal (data) by a pulse position modulation (PPM) method or the like. The encoding circuit encodes the transmission signal (data) by the Manchester method or the like. The serial I/O performs serial/parallel conversion of a data string. The command processing circuit controls the flow of these signals.

Control circuit unit LO is provided in semiconductor chip 2 or TFT 3. Specifically, control circuit unit LO may be entirely provided in semiconductor chip 2 or TFT 3, or may be partially provided in semiconductor chip 2 and another part may be provided in TFT 3.

More specifically, memory control circuit unit LO1 and the other control circuit unit LO2 may be independently provided in semiconductor chip 2 or TFT 3.

Memory control circuit unit LO1 being provided in semiconductor chip 2 means that semiconductor chip 2 or a part thereof is used as memory control circuit unit LO1 or that semiconductor chip 2 or a part thereof performs the function of memory control circuit unit LO1.

Memory control circuit unit LO1 being provided in TFT 3 means that TFT 3 or a part thereof is used as memory control circuit unit LO1 or that TFT 3 or a part thereof performs the function of memory control circuit unit LO1.

The other control circuit unit LO2 being provided in semiconductor chip 2 means that semiconductor chip 2 or a part thereof is used as the other control circuit unit LO2 or that semiconductor chip 2 or a part thereof performs the function of the other control circuit unit LO2.

The other control circuit unit LO2 being provided in TFT 3 means that TFT 3 or a part thereof is used as the other control circuit unit LO2 or that TFT 3 or a part thereof performs the function of the other control circuit unit LO2.

The other control circuit unit LO2 is preferably provided in semiconductor chip 2 from the viewpoint of higher-speed operation of the wireless communication device. In this case, memory control circuit unit LO1 may be provided in semiconductor chip 2 or TFT 3. Memory control circuit unit LO1 is preferably provided in semiconductor chip 2 from the viewpoint of higher-speed operation of the wireless communication device. From the viewpoint of further reducing the number of wirings of the wireless communication device, memory control circuit unit LO1 is preferably provided in TFT 3.

In the wireless communication device of the present embodiment, not all of the units, such as the radio circuit unit, the memory unit, the power supply circuit unit, and the control circuit unit are provided in one of the TFT or the semiconductor chip. Some of these units (for example, at least a radio circuit unit and a power supply circuit unit) are provided in a semiconductor chip while the other units (for example, at least a memory unit, particularly, a unique ID memory unit) are provided in the TFT. The semiconductor chip (or a part thereof) preferably performs the function of at least the radio circuit unit and the power supply circuit unit while the TFT (or part thereof) performs the function of at least the memory unit (particularly, the unique ID memory unit). As a result, as compared to the TFT-based wireless communication device of the related art, the operation speed and reliability that cannot be realized by the TFT-based wireless communication device of the related art are achieved while sufficiently suppressing an increase in manufacturing cost per device.

However, the wireless communication device according to the present embodiment is not limited to the device in which the memory unit is provided in the TFT. Common circuits (for example, a radio circuit and a power supply circuit) between the wireless communication devices are provided in the semiconductor chip, and circuits (for example, a memory unit and a control circuit unit) that can be changed for each wireless communication device may be provided in the TFT.

The wireless communication device according to the present embodiment will be detailed below with reference to embodiments. Among the following embodiments, from the viewpoint of further reducing the manufacturing cost per wireless communication device and further preventing a decrease in the operation speed and reliability, wireless communication devices 10A to 10C of Embodiments 1 to 3 are preferable, wireless communication devices 10B to 10C of Embodiments 2 and 3 are more preferable, and wireless communication device 10B of Embodiment 2 is further preferable.

### Embodiment 1

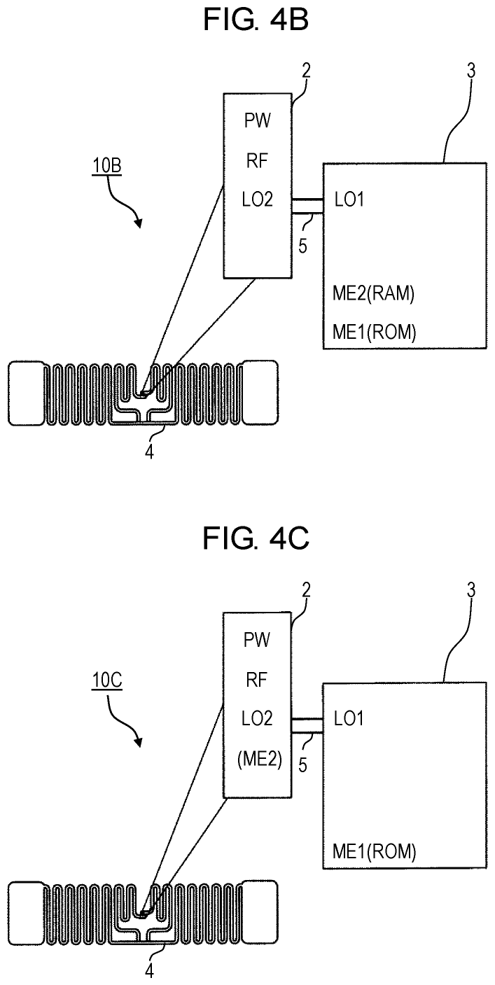

As illustrated in FIG. 4A, wireless communication device 10A of Embodiment 1 includes a circuit board, semiconductor chip 2 mounted on the circuit board, TFT 3 provided on the circuit board, and antenna 4 provided on the circuit board, wiring 5, and a protection layer. FIG. 4A is a schematic circuit diagram illustrating an arrangement of radio circuit unit RF, memory unit ME (ME1 and ME2), power supply circuit unit PW, and control circuit unit LO (LO1 and LO2) in the circuit configuration of the wireless communication device according to Embodiment 1 included in the present embodiment. In FIG. 4A, the circuit board and the protection layer are omitted.

In the present embodiment, radio circuit unit RF and power supply circuit unit PW are provided on semiconductor chip 2.

Memory unit ME includes at least unique ID memory unit ME1, and may or may not include the other memory unit ME2. Unique ID memory unit ME1 is provided in TFT 3, and is implemented by a ROM. In a case that memory unit ME includes another memory unit ME2, the other memory unit ME2 is provided in semiconductor chip 2, and is implemented by a RAM.

Control circuit unit LO includes memory control circuit unit LO1 and another control circuit unit LO2. Both memory control circuit unit LO1 and the other control circuit units LO2 are provided in semiconductor chip 2.

### Embodiment 2

As illustrated in FIG. 4B, wireless communication device 10B of Embodiment 2 includes a circuit board, semiconductor chip 2 mounted on the circuit board, TFT 3 provided on the circuit board, and antenna 4 provided on the circuit board, wiring 5, and a protection layer. FIG. 4B is a schematic circuit diagram illustrating an arrangement of radio circuit unit RF, memory unit ME (ME1 and ME2), power supply circuit unit PW, and control circuit unit LO (LO1 and LO2) in the circuit configuration of the wireless communication device according to Embodiment 2 of the present embodiment. In FIG. 4B, the circuit board and the protection layer are omitted.

In the present embodiment, radio circuit unit RF and power supply circuit unit PW are provided on semiconductor chip 2.

Memory unit ME includes unique ID memory unit ME1 and another memory unit ME2.

Unique ID memory unit ME1 and the other memory unit ME2 are provided in TFT 3. A ROM is used for unique ID memory unit ME1. A RAM is used for the other memory unit ME2.

Control circuit unit LO includes memory control circuit unit LO1 and another control circuit unit LO2. Memory control circuit unit LO1 is provided in TFT 3. The other control circuit unit LO2 is provided in semiconductor chip 2.

### Embodiment 3

As illustrated in FIG. 4C, wireless communication device 10C of Embodiment 3 includes a circuit board, semiconductor chip 2 mounted on the circuit board, TFT 3 provided on the circuit board, and antenna 4 provided on the circuit board, wiring 5, and a protection layer. FIG. 4C is a schematic circuit diagram illustrating an arrangement of radio circuit unit RF, memory unit ME (ME1 and ME2), power supply circuit unit PW, and control circuit unit LO (LO1 and LO2) in the circuit configuration of the wireless communication device according to Embodiment 3 included in the present embodiment. In FIG. 4C, the circuit board and the protection layer are omitted.

In the present embodiment, radio circuit unit RF and power supply circuit unit PW are provided on semiconductor chip 2.

Memory unit ME includes at least unique ID memory unit ME1, and the other memory unit ME2 may or may not be included. Unique ID memory unit ME1 is provided in TFT 3, and is implemented by a ROM. When memory unit ME includes another memory unit ME2, the other memory unit ME2 is provided in semiconductor chip 2, and is implemented by a RAM.

Control circuit unit LO includes memory control circuit unit LO1 and another control circuit unit LO2. Memory control circuit unit LO1 is provided in TFT 3. The other control circuit unit LO2 is provided in semiconductor chip 2.

### Method for Manufacturing Wireless Communication Device According to Embodiment A

The wireless communication device according to Embodiment A may be manufactured by a method including the following steps:

Step P of mounting semiconductor chip 2 on circuit board 1; and

Step Q of forming TFT 3, antenna 4, and wiring 5 on circuit board 1 by printing.

The order of performing steps P and Q is not particularly limited as long as the wireless communication device of the present embodiment can be manufactured. For example, step Q may be performed after step P, and after performing step P during the execution of step Q, the remaining step Q may be performed, or step P may be performed after step Q. In a preferred method for manufacturing a wireless communication device from the viewpoint of further reducing the manufacturing cost and further improving the simplicity of manufacturing, in step Q, TFT 3 is formed by a printing, and in step P, semiconductor chip 2 is mounted, and then, in step Q, antenna 4 and wiring 5 are formed by a printing.

A method for manufacturing the above-described preferable wireless communication device will be described.

A method for manufacturing a wireless communication device includes:

Step A of forming TFT 3 on circuit board 1 by a printing;

Step B of mounting semiconductor chip 2 on circuit board 1; and

Step C of forming antenna 4 and wiring 5 on circuit board 1 by a printing.

In the present embodiment, the method for manufacturing the wireless communication device further includes:

Step D of forming protection layer 6 by a printing method on circuit board 1 and on semiconductor chip 2, TFT 3, antenna 4, and wiring 5 mounted or formed on circuit board 1.

### Step A

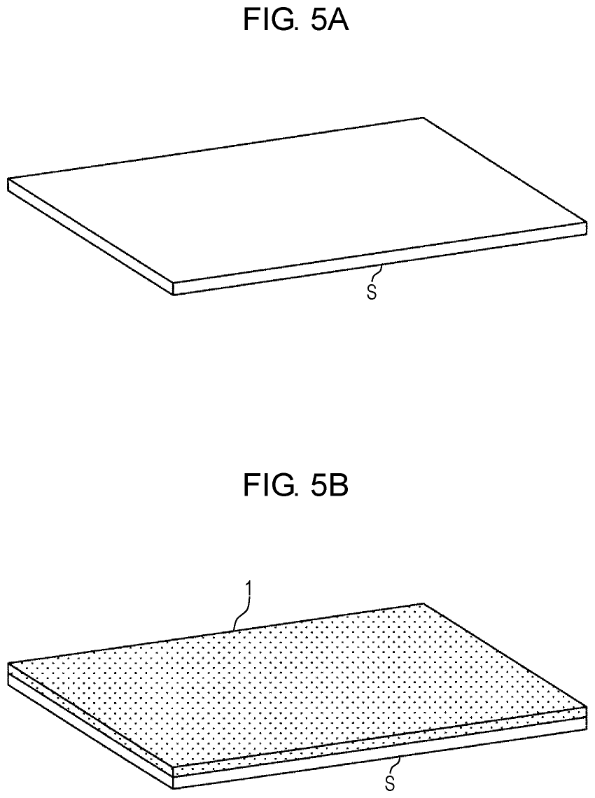

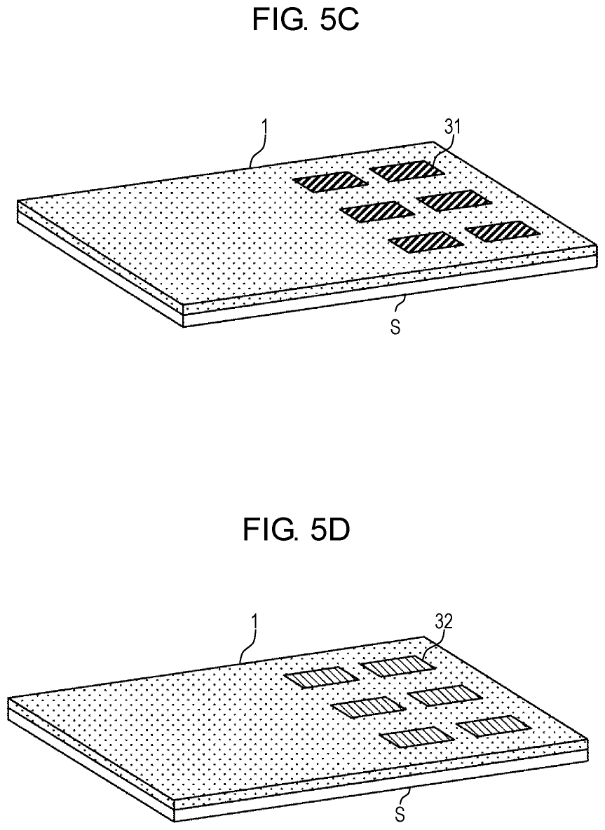

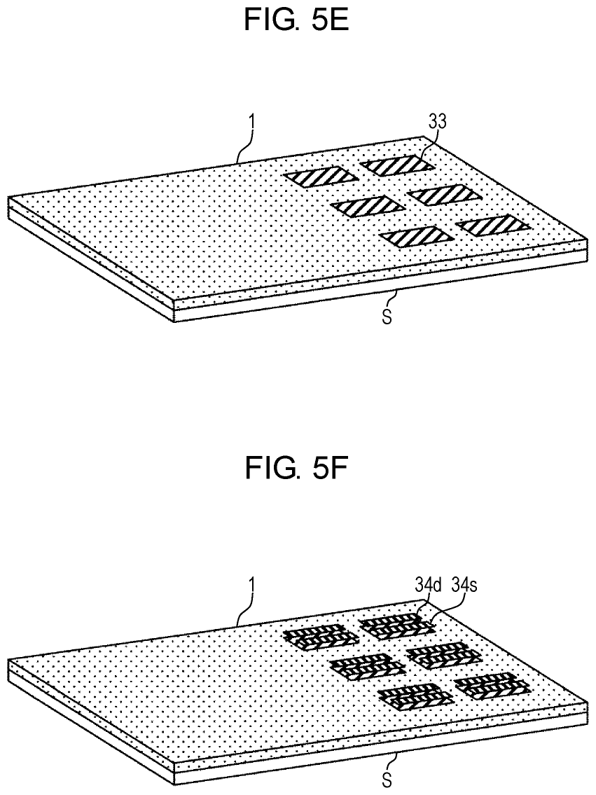

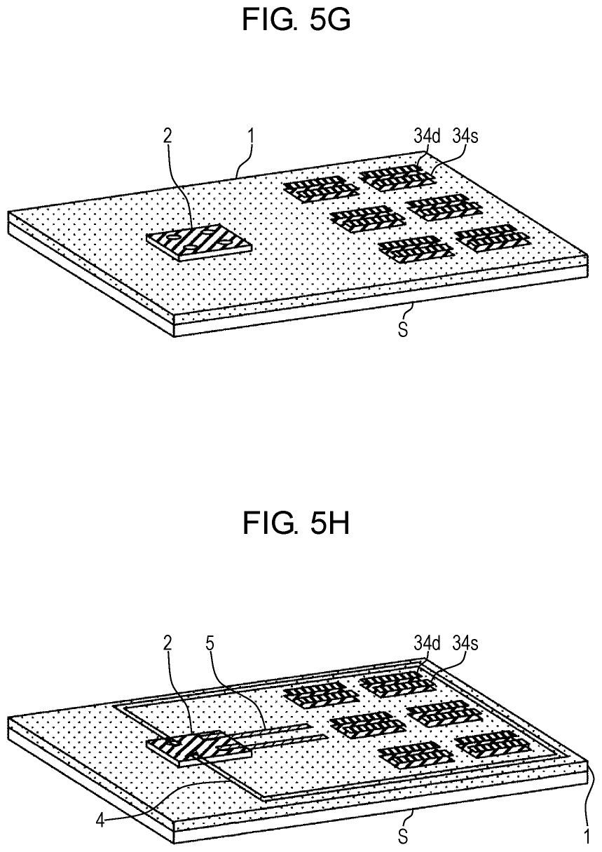

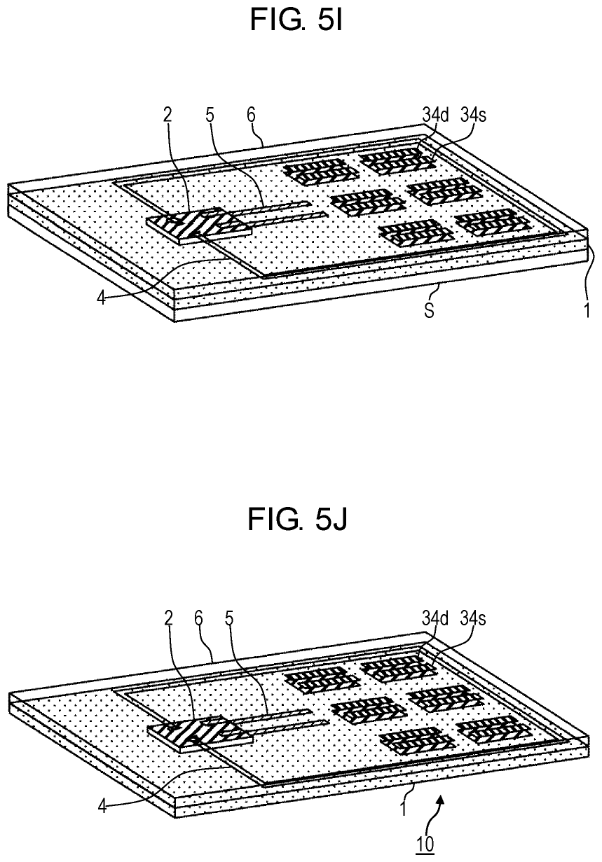

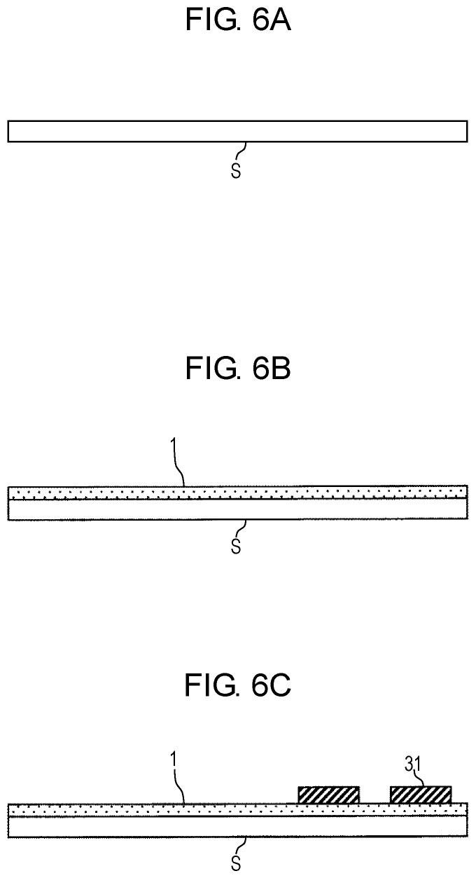

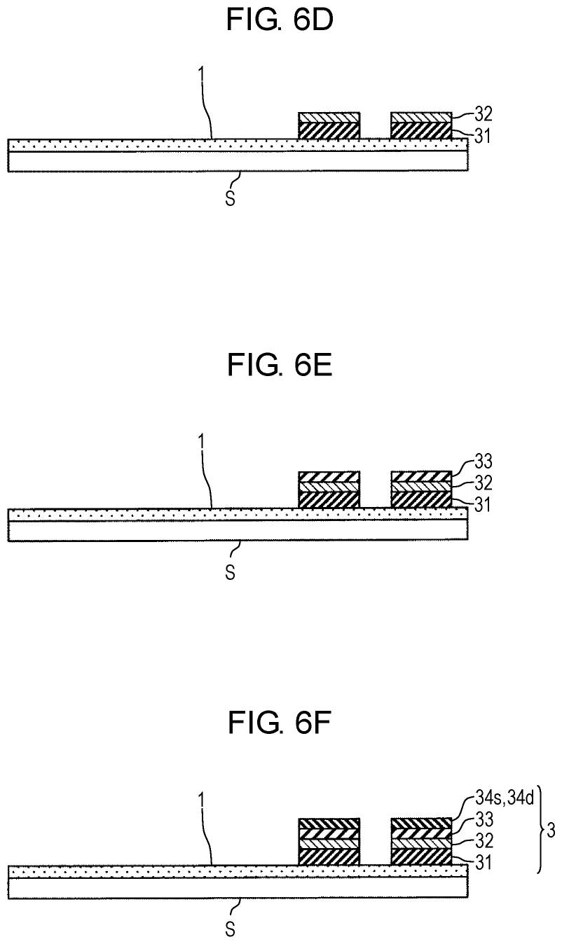

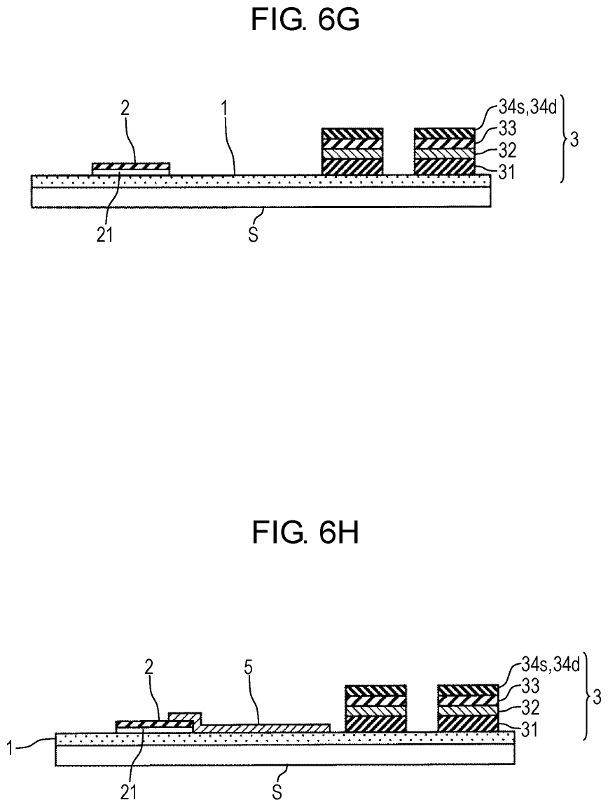

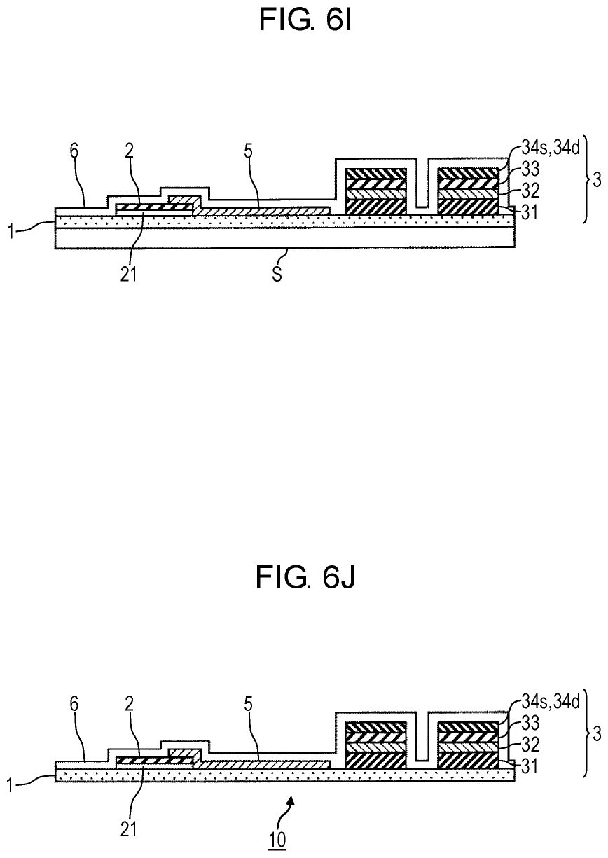

In step A, circuit board 1 formed on support board S may be used as circuit board 1 according to the thickness thereof. For example, depending on the thickness of circuit board 1 to be manufactured or used, support board S is prepared as illustrated in FIGS. 5A and 6A, after circuit board 1 is manufactured on support board S as illustrated in FIGS. 5B and 6B, TFT 3 is formed on circuit board 1 by a printing. In a case that the thickness of circuit board 1 is sufficient to support semiconductor chip 2 and the like on circuit board 1, circuit board 1 may be manufactured and used without support board S. FIGS. 5A and 6A are a schematic view and a schematic cross-sectional view, respectively, illustrating a step of preparing a support board in the method for manufacturing the wireless communication device according to the present embodiment. FIGS. 5B and 6B are a schematic view and a schematic cross-sectional view, respectively, illustrating a step of manufacturing a circuit board in the method for manufacturing the wireless communication device according to the present embodiment.

Examples of the material of support board S are glass, alumina, a glass-alumina composite material, silicon, epoxy resin, polyimide resin, and stainless steel. In the present embodiment, a glass board is used as support board S. The thickness of support board S preferably ranges from about 50 μm to about 1800 μm, more preferably from about 200 μm to about 800 μm (for example, about 700 μm). In the present embodiment, support board S is peeled off from the wireless communication device after the wireless communication device is manufactured.

Circuit board 1 may be manufactured by any molding or coating technique. Examples of such a molding or coating technique include molding methods, such as injection molding, injection compression molding, compression molding, extrusion molding, blow molding, press molding, and foam molding, coating methods, such as spin coating, wire bar coating, brush coating, spray coating, and gravure roll coating, printing methods, such as ink jet printing, screen printing, gravure printing, gravure offset printing, reverse offset printing, flexo printing, and the like. From the viewpoint of further reducing the manufacturing cost and further improving the simplicity of manufacturing the circuit board, the circuit board is preferably manufactured by a coating method (particularly, a spin coating method). A coating liquid used in a coating method for manufacturing a circuit board or an ink used in a printing method may have a desired circuit board material (polymer) dispersed in a solvent, or the polymer may be dissolved in a solvent. After the circuit board is manufactured by the coating method or the printing method, in the present embodiment, the solvent is dried. At this moment, curing may occur if necessary. In the present embodiment, the drying temperature (curing temperature) ranges from 150 to 250° C., preferably from 150 to 220° C., and for example, is, e.g. 180° C.

TFT 3 is formed by a printing, but TFT 3 is not necessarily formed by a printing method and may be formed by any thin film forming techniques. Examples of the printing method include an ink jet printing method, a screen printing method, a gravure printing method, a gravure offset printing method, a reverse offset printing method, a flexographic printing method, and the like. Examples of the thin film forming technique include, in addition to the printing method described above, a sputtering method, a vapor deposition method, an ion plating method, and a vacuum film forming method such as a plasma CVD method. From the viewpoint of further reducing the manufacturing cost, further improving the security performance with a simple structure, and further improving the simplicity of manufacturing the TFT, the TFT is preferably formed by a printing method (in particular, an ink jet method).

A method for forming TFT 3 by a printing method will be described in detail below. A method for forming a bottom gate-top contact type organic TFT as TFT 3 will be described, but another TFT may be formed by a known method.

TFT 3 may be formed by a method that includes the following steps:

a step of forming gate electrode 31;

a step of forming insulating layer 32 on gate electrode 31;

a step of forming semiconductor layer 33 on insulating layer 32; and

a step of forming source electrode 34s and drain electrode 34d such that semiconductor layer 33 is disposed between the source electrode and the drain electrode in plan view.

### Step of Forming Gate Electrode

Gate electrode 31 is formed at a predetermined position on circuit board 1, as illustrated in FIGS. 5C and 6C. Examples of the material of gate electrode 31 are metal materials such as gold (Au), silver (Ag), copper (Cu), nickel (Ni), chromium (Cr), cobalt (Co), magnesium (Mg), calcium (Ca), platinum (Pt), molybdenum (Mo), iron (Fe) and/or zinc (Zn), conductive oxides such as tin oxide (SnO₂), indium tin oxide (ITO), tin oxide containing fluorine (FTO), ruthenium oxide (RuO₂), iridium oxide (IrO₂), and platinum oxide (PtO₂), or the like. FIGS. 5C and 6C are a schematic view and a schematic cross-sectional view, respectively, illustrating a step of forming a gate electrode in the method for manufacturing the wireless communication device according to the present embodiment.

The method for forming the gate electrode is not particularly limited, and an electrode forming method of the related art may be employed. From the viewpoint of further reducing the manufacturing cost, further improving the security performance with a simple structure, and further improving the simplicity of manufacturing the TFT, gate electrode 31 is preferably formed by a printing method (particularly, ink jet printing method). In the present embodiment, a gate electrode is formed by depositing silver with silver nano-ink by an ink jet printing method. The thickness of gate electrode 31 ranges preferably from about 10 nm to about 100 nm, more preferably from about 15 nm to about 50 nm (for example, about 30 nm). The ink used in the printing method for forming the gate electrode is an ink (for example, a silver nano-ink) containing conductive material, such as the above-described metal material, and/or conductive oxide, that is, at least one of the metal material and the conductive oxide. In the present embodiment, the ink for forming the gate electrode is an ink containing conductive material in solvent. After the forming of the gate electrode, in the present embodiment, the solvent is dried. In the present embodiment, the drying temperature ranges from 100 to 200° C., preferably from 120 to 180° C., and is, e.g. for example, 150° C.

### Step of Forming Insulating Layer

Insulating layer 32 is formed on gate electrode 31, as illustrated in FIGS. 5D and 6D. Insulating layer 32 may be a resin-based or inorganic insulating-based insulating film. Examples of the resin-based insulating film include a film made of epoxy resin, polyimide (PI) resin, polyphenylene ether (PPE) resin, polyphenylene oxide resin (PPO), or polyvinyl pyrrolidone (PVP) resin. On the other hand, examples of an inorganic insulating-based insulating film include a film made of metal oxides, such as tantalum oxide (such as Ta₂O₅), aluminum oxide (such as Al₂O₃), silicon oxide (such as SiO₂), zeolite oxide (such as ZrO₂), titanium oxide (such as TiO₂), yttrium oxide (such as Y₂O₃), lanthanum oxide (such as La₂O₃), hafnium oxide (such as HfO₂) or a nitride of one of these metals. A film made of dielectric material, such as barium titanate (BaTiO₃), strontium titanate (SrTiO₃), or calcium titanate (CaTiO₃) may be used. Insulating layer 32 is preferably a resin-based insulating film (particularly, a polyimide resin film). FIGS. 5D and 6D are a schematic view and a schematic cross-sectional view, respectively, illustrating a step of forming an insulating layer in the method for manufacturing the wireless communication device according to the present embodiment.

The formation of insulating layer 32 may be performed by a printing, a vacuum evaporation method, or a sputtering method. In the case of forming a resin-based insulating film, in particular, insulating layer 32 can be formed by applying a coating agent (may be a resist containing a photosensitive agent) in which a resin material is mixed with a medium to a formation position, followed by drying, heat treatment, and curing. On the other hand, in the case of an inorganic insulating-based insulating film, insulating layer 32 may be formed by a thin film formation method using a mask (such as a sputtering method). From the viewpoint of further reducing the manufacturing cost, further improving the security performance with a simple structure, and further improving the simplicity of manufacturing the TFT, insulating layer 32 is preferably formed by a printing method (particularly, ink jet printing method). In the present embodiment, a polyimide insulating layer is formed with an ink of a polyimide solution or a dispersion liquid by an ink jet printing method. The thickness of insulating layer 32 preferably in ranges from about 0.1 μm to about 2 μm, more preferably from about 0.2 μm to about 1 μm (for example, about 0.3 μm). After the insulating layer is formed by the printing method, in the present embodiment, the solvent is dried. At this moment, curing may occur if necessary. In the present embodiment, the drying temperature (curing temperature) ranges from 150 to 250° C., preferably from 150 to 220° C., and is, for example, 180° C.

### Step of Forming Semiconductor Layer

Semiconductor layer 33 is formed on insulating layer 32, as illustrated in FIGS. 5E and 6E. Semiconductor layer 33 is preferably an organic semiconductor. As a material for the organic semiconductor, a material having high mobility is preferable, and for example, pentacene may be used. The organic semiconductor material that can be used in the present embodiment is not limited thereto and includes nanocarbon materials (for example, carbon nanotubes, SiGe nanowires, fullerenes, and modified fullerenes), inorganic-organic mixed materials (for example, composites of (C₆H₅C₂H₄NH₃) and SnI₄), and the like, in addition to high-molecular materials (for example, polythiophene or derivatives thereof), low-molecular materials (for example, pentacene and solubilized pentacene). FIGS. 5E and 6E are a schematic view and a schematic cross-sectional view, respectively, illustrating a step of forming a semiconductor layer in the method for manufacturing the wireless communication device according to the present embodiment.

The method for forming semiconductor layer 33 is not particularly limited, and any method may be used as long as semiconductor layer may be formed on insulating layer 32. In the manufacturing method of the present embodiment, in particular, from the viewpoint of further reducing the manufacturing cost, further improving the security performance with a simple structure, and further improving the simplicity of manufacturing the TFT, semiconductor layer 33 is formed preferably by a printing method (particularly, ink jet printing method). In the present embodiment, for example, in a case that a polymer organic semiconductor layer (for example, polythiophene such as Poly-3-hexylthiophene (P3HT) or a derivative thereof) is formed, a printing method can be suitably used. More specifically, semiconductor layer 33 may be formed by, for example, spraying a P3HT solution onto the insulating film by an ink jet method and then drying the solution. In the case of a low-molecular organic semiconductor (for example, pentacene), organic semiconductor layer 33 may be formed by a vapor deposition process. The thickness of semiconductor layer 33 preferably ranges from about 50 nm to about 150 nm, more preferably from about 80 nm to about 120 nm, and is, for example, about 100 nm. After the semiconductor layer is formed by the printing method, in the present embodiment, the solvent is dried. In the present embodiment, the drying temperature ranges from 150 to 250° C., preferably from 180 to 220° C., and is, for example, 200° C.

### Steps of Forming Source and Drain Electrodes

Source electrode 34s and drain electrode 34d are formed such that semiconductor layer 33 is disposed between the source electrode 34s and drain electrode 34d in a plan view. The plan view means a view which is viewed from above the device in the thickness direction of the TFT. Here, “up” means “upward” when the TFT is formed on the surface of the circuit board as a substantially horizontal plane. In more detail, source electrode 34s and drain electrode 34d may be formed on semiconductor layer 33 so as to be separated away from each other as illustrated in FIGS. 5F and 6F, or may be formed on insulating layer 32 so as to be in contact with semiconductor layer 33. More specifically, source electrode 34s and drain electrode 34d may be formed on semiconductor layer 33 so as to be separated away from each other. Alternatively, source electrode 34s and drain electrode 34d may be formed on insulating layer 32 so as to be separated away from each other such that semiconductor layer 33 is disposed between source electrode 34s and drain electrode 34d on insulating layer 32 and is in contact with these electrodes. FIGS. 5F and 6F are a schematic view and a schematic cross-sectional view, respectively, illustrating a step of forming a source electrode and a drain electrode in the method for manufacturing the wireless communication device according to the present embodiment.

As a material of source electrode 34s and drain electrode 34d, a metal having high conductivity is preferable, and for example, metal materials, such as silver (Ag), copper (Cu), nickel (Ni), aluminum (Al), and stainless steel (SUS) may be used. The formation of source electrode 34s and drain electrode 34d is not particularly limited, and an electrode forming method of the related art may be employed. That is, the source electrode and the drain electrode may be formed by a printing method, or a vacuum evaporation method, or a sputtering method. From the viewpoint of further reducing the manufacturing cost, further improving the security performance with a simple structure, and further improving the simplicity of manufacturing the TFT, source electrode 34s and drain electrode 34d are preferably formed by a printing method (particularly, ink jet printing method). In the present embodiment, source electrode 34s and drain electrode 34d are formed by depositing silver with silver nano-ink by an ink jet printing method. The thickness of each of source electrode 34s and drain electrode 34d preferably ranges from about 0.02 μm to about 10 μm, more preferably from about 0.03 μm to about 1 μm (and is, for example, about 0.1 μm). The ink used in the printing method for forming source electrode 34s and drain electrode 34d is the ink containing the above-described metal material (for example, silver nano-ink). In the present embodiment, the ink for forming source electrode 34s and drain electrode 34d is an ink containing a metal material dispersed in a solvent. After source electrode 34s and drain electrode 34d are formed, in the present embodiment, the solvent is dried. In the present embodiment, the drying temperature ranges from 100 to 200° C., preferably from 120 to 180° C., and is for example, 150° C.

### Step B

In step B, semiconductor chip 2 is mounted on circuit board 1 as illustrated in FIGS. 5G and 6G. “Mounting” refers to bonding semiconductor chip 2 manufactured or obtained in advance to the circuit board by a known bonding means such as adhesive 21 or the like. As the semiconductor chip (particularly, a silicon chip), for example, commercially available products such as NXP Semiconductors N.V., Impinj, Inc., or Alien Technology, may be used. The adhesive may be any adhesive that is conventionally used for bonding to a board in the field of semiconductor chips. FIGS. 5G and 6G are a schematic view and a schematic cross-sectional view, respectively, illustrating a step of mounting a semiconductor chip in the method for manufacturing the wireless communication device according to the present embodiment.

### Step C

In step C, as illustrated in FIGS. 5H and 6H, antenna 4 and wiring 5 are formed on circuit board 1 by a printing method. Antenna 4 and wiring 5 are formed by a printing method, but may not necessarily be formed by a printing method, and may be formed by any thin film forming technique, like TFT 3. As a thin film forming technique for forming antenna 4 and wiring 5, for example, a thin film forming technique similar to the thin film forming technique exemplified in the description of TFT 3 may be used. From the viewpoint of further reducing the manufacturing cost and further improving the simplicity of manufacturing, antenna 4 and wiring 5 are preferably manufactured by a printing method (particularly, an ink jet printing method). The ink used in the printing method for forming antenna 4 and wiring 5 is an ink (for example, a silver nano-ink) containing a conductive material, such as silver (Ag), copper (Cu), nickel (Ni), aluminum (Al), and stainless steel (SUS). In the present embodiment, the ink for forming antenna 4 and wiring 5 is an ink containing the conductive material dispersed in a solvent. After antenna 4 and wiring 5 are formed, in the present embodiment, the solvent is dried. In the present embodiment, the drying temperature ranges from 100 to 200° C., preferably from 120 to 180° C., and is, for example, 150° C. FIGS. 5H and 6H are a schematic view and a schematic cross-sectional view, respectively, illustrating a step of forming an antenna and a wiring in the method for manufacturing the wireless communication device according to the present embodiment.

### Step D

In step D, as illustrated in FIGS. 5I and 6I, protection layer 6 is formed by a printing method on circuit board 1 and semiconductor chip 2, TFT 3, antenna 4, and wiring 5 mounted or formed on circuit board 1. FIGS. 5I and 6I are a schematic view and a schematic cross-sectional view, respectively, illustrating a step of forming a protection layer in the method for manufacturing the wireless communication device according to the present embodiment.

The method for forming protection layer 6 is not particularly limited and can be formed by any of the coating methods and printing methods exemplified in the description of circuit board 1, for example. From the viewpoint of further reducing the manufacturing cost and further improving the simplicity of manufacturing the wiring, the protection layer is preferably manufactured by a printing method (particularly, an ink jet printing method). The ink used in the printing method for manufacturing the protection layer is an ink containing a desired polymer. In the ink for forming the protection layer, the polymer may be dispersed in a solvent, or the polymer may be dissolved in the solvent. After the protection layer is formed, in the present embodiment, the solvent is dried. At this time, curing may occur if necessary. In the present embodiment, the drying temperature (curing temperature) ranges from 150 to 250° C., preferably from 150 to 220° C., and is, for example, 180° C.

After protection layer 6 is formed, in the present embodiment, as illustrated in FIGS. 5J and 6J, support board S is peeled off to obtain a wireless communication device. FIGS. 5J and 6J are a schematic view and a schematic cross-sectional view, respectively, illustrating a step of peeling off a support board in the method for manufacturing the wireless communication device according to the present embodiment. In FIGS. 5J and 6J, apparently, all TFTs 3 do not appear to be electrically connected to semiconductor chip 2, but wiring 5 is illustrated in a simplified manner in consideration of the complexity of wiring 5 formed under protection layer 6 (that is, between circuit board 1 and protection layer 6). Actually, all TFTs 3 are electrically connected directly or indirectly to semiconductor chip 2 by wiring 5 formed under protection layer 6 (that is, between circuit board 1 and protection layer 6). The simplification of wiring 5 in FIGS. 5J and 6J is the same in FIGS. 5H to 5I and 6H to 6I. The TFT being directly connected to the semiconductor chip means that the connection between the TFT and the semiconductor chip is achieved by a wiring without intervening members other than the wiring (for example, another TFT and the other) between them. The TFT being indirectly connected to the semiconductor chip means that the connection between the TFT and the semiconductor chip is achieved by members (for example, another TFT and the like) other than a wiring and the wiring interposed between them.

### Wireless Communication Device According to Embodiment B

The wireless communication device according to Embodiment B of the present disclosure is a wireless communication device particularly useful for additionally writing information (for example, a unique ID and/or information linked to the unique ID, that is, at least one of the unique ID and information linked to the unique ID) in the wireless communication device according to Embodiment A. Embodiment B of the present disclosure includes the following Embodiments b1 and b2 and may be an embodiment provided by combining Embodiments b1 and b2.

### Embodiment B1

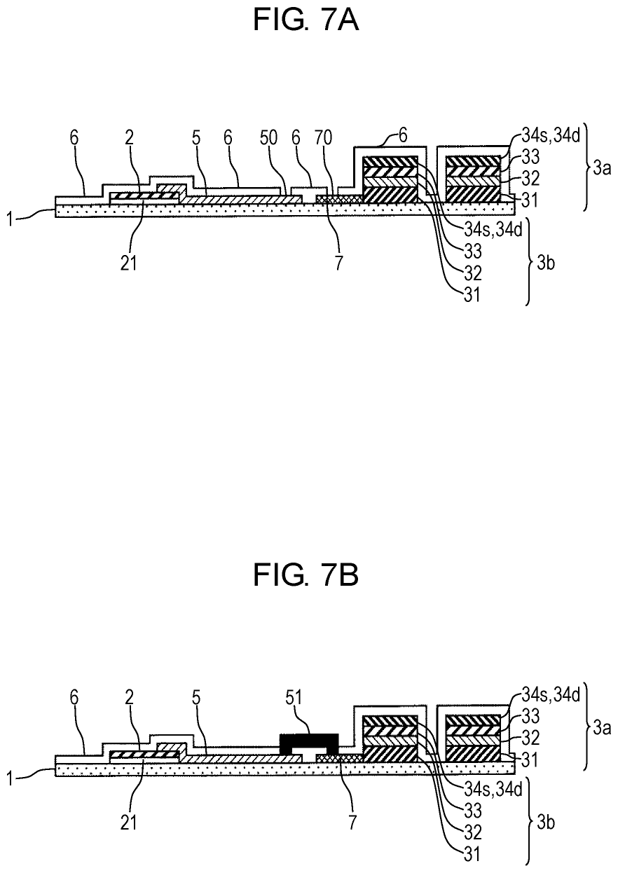

A wireless communication device according to Embodiment b1 is identical to the wireless communication device according to Embodiment A except for the following items (b1-1) to (b1-3) (see FIGS. 7A and 7B).

(b1-1) The wireless communication device according to the present embodiment requires protection layer 6 on circuit board 1 on the side where semiconductor chip 2 and the like are formed.
(b1-2) The wireless communication device according to the present embodiment includes, as TFT 3, one or more “connected TFTs” and one or more “non-connected TFTs”. The connected TFT is a TFT that is electrically connected to semiconductor chip 2 by wiring 5 formed below protection layer 6 (that is, between circuit board 1 and protection layer 6), and is denoted by the reference numeral, “3a” in FIGS. 7A and 7B. In these drawings, TFT 3a does not appear to be electrically connected to semiconductor chip 2, but wiring 5 is illustrated simply in consideration of the complexity of wiring 5 formed below protection layer 6 (that is, between circuit board 1 and protection layer 6). Actually, TFT 3a is directly or indirectly and electrically connected to semiconductor chip 2 by wiring 5 formed below protection layer 6 (that is, between circuit board 1 and protection layer 6). The non-connected TFT is a TFT that is not electrically connected to semiconductor chip 2 by wiring 5 formed below protection layer 6 (that is, between circuit board 1 and protection layer 6), and is denoted by the reference numerals, “3b” in FIGS. 7A and 7B. In the present embodiment, connected TFT 3a and non-connected TFT 3b are formed below protection layer 6 (that is, between circuit board 1 and protection layer 6), as illustrated in FIGS. 7A and 7B.
(b1-3) In the wireless communication device of the present embodiment, as illustrated in FIG. 7A, non-connected TFT 3b includes terminal 7. Terminal 7 is an exposed terminal having exposed surface 70 that is at least partially exposed from protection layer 6. Terminal 7 is connected to a desired electrode of non-connected TFT 3b. The number of terminals 7 is not particularly limited and may be one or more per one non-connected TFT 3b, for example. Exposed surface 70 can be easily formed by masking at least a part of the surface of terminal 7 when protection layer 6 is formed. That is, by a window formed in protection layer 6 allows at least a part of the surface (exposed surface 70) of terminal 7 to be exposed from the window.

In the wireless communication device of the present embodiment, in addition to non-connected TFT 3b including terminal 7 instead of including terminal 7 having exposed surface 70 that is at least partially exposed from protection layer 6, semiconductor chip 2 may include an exposed terminal having an exposed surface that is at least partially exposed from the protection layer. Such terminals are connected to desired portions of the semiconductor chip. The number of the exposed terminals is not particularly limited and may be, for example, one or more per one semiconductor chip. The exposed surface of the exposed terminal can be formed by the same method as exposed surface 70 of terminal 7.

As a material for terminal 7, a metal having high conductivity is preferable, and for example, metal materials, such as silver (Ag), copper (Cu), nickel (Ni), aluminum (Al), or stainless steel (SUS), may be used. Terminal 7 is preferably a silver terminal from the viewpoint of simplicity of a reduction reaction which will be described later. Terminal 7 is preferably a printed component from the viewpoints of further reducing the manufacturing cost, further improving the security performance with a simple structure, and further improving the simplicity of manufacturing the wiring.

In the wireless communication device of the present embodiment, in the above structure, in the case that non-connected TFT 3b includes terminal 7 which is a terminal exposed, non-connected TFT 3b may be electrically connected to semiconductor chip 2 by wiring 51 formed on protection layer 6 on exposed surface 70 of terminal 7 from protection layer 6, as illustrated in FIG. 7B. In the case that semiconductor chip 2 includes an exposed terminal, the semiconductor chip may be electrically connected to non-connected TFT 3b by the wiring formed on the protection layer on the exposed surface of the exposed terminal from the protection layer. For this reason, in the wireless communication device according to the present embodiment, even after the completion of manufacturing, TFTs (particularly, memory unit ME (preferably ROM)) may be added by simply forming wiring 51 on protection layer 6 in various scenes by a simple method, such as a printing method (particularly, ink jet printing method). As a result, even if a different unique ID is assigned to each of the wireless communication devices, as compared to silicon-based wireless communication devices, it is possible to not only further sufficiently reduce the manufacturing cost per device, but also prevent the reduction in the operation speed and reliability, and more sufficiently prevent security-related problems such as fake and forgery with a simpler structure. In particular, in the wireless communication device according to the present embodiment, since the substantial addition of the TFT (particularly, memory unit ME (preferably, ROM)) is achieved, and the information (particularly, the unique ID and/or the information linked to the unique ID, that is, at least one of the unique ID and the information linked to the unique ID) cannot be rewritten, it is possible to more sufficiently prevent security-related problems such as fake and forgery.

Terminal 7, which is an exposed terminal, may include a metal oxide layer on exposed surface 70 exposed from protection layer 6. The exposed surface of terminal 7 is oxidized by exposure of the surface to form a metal oxide layer. For example, when terminal 7 is a silver terminal, a silver oxide layer is formed on exposed surface 70. Even when terminal 7 includes a metal oxide layer on exposed surface 70, the metal oxide layer may be removed when substantial addition of TFTs is required, such as when performing additional writing in various scenes. For example, a silver oxide layer easily undergoes a reduction reaction at about 200° C. to become silver without a reducing agent. Further, for example, when a reducing agent is used, the silver oxide layer more easily undergoes a reduction reaction at a lower temperature to change into silver. As a method for removing the metal oxide layer, for example, a method for spraying a reducing agent solution at a predetermined temperature onto the metal oxide layer by a printing method (particularly, an ink jet printing method) is used.

As illustrated in FIGS. 7A and 7B, one end of wiring 51 is electrically connected to terminal 7 and the other end is electrically connected to wiring 5 having exposed surface 50 that is partially exposed from protection layer 6. The connection target at the other end of wiring 51 is not limited to wiring 5 and is, for example, a terminal formed on semiconductor chip 2, and may be a terminal having an exposed surface that is at least partially exposed from protection layer 6 or may be an antenna having exposed surface 50 that is partially exposed from protection layer 6.

Wiring 51 is preferably a printed component from the viewpoints of further reducing the manufacturing cost, further improving the security performance with a simple structure, and further improving the simplicity of manufacturing the wiring. Wiring 51 being a printed component means that wiring 51 is a component manufactured by a printing method.

The thickness of wiring 51 may be determined within the same range as the thickness of wiring 5.

Wiring 51 is not particularly limited as long as the wiring is made of conductive material, and may be made of, for example, metal material, such as silver (Ag), copper (Cu), nickel (Ni), aluminum (Al), and stainless steel (SUS).

The wireless communication device of the present embodiment may be manufactured by the same method as the manufacturing method of the wireless communication device according to Embodiment A, except that terminal 7 is formed, exposed surface 70 is formed on at least a part of the surface of terminal 7, and the other end of wiring 51 forms an exposed surface (for example, exposed surface 50) for electrical connection.

The wireless communication device of the present embodiment may include an additional protection layer on wiring 51. The additional protection layer may be selected from the same range as protection layer 6 described above. The further protection layer may be formed by a method by which protection layer 6 can be formed.

### Embodiment B2

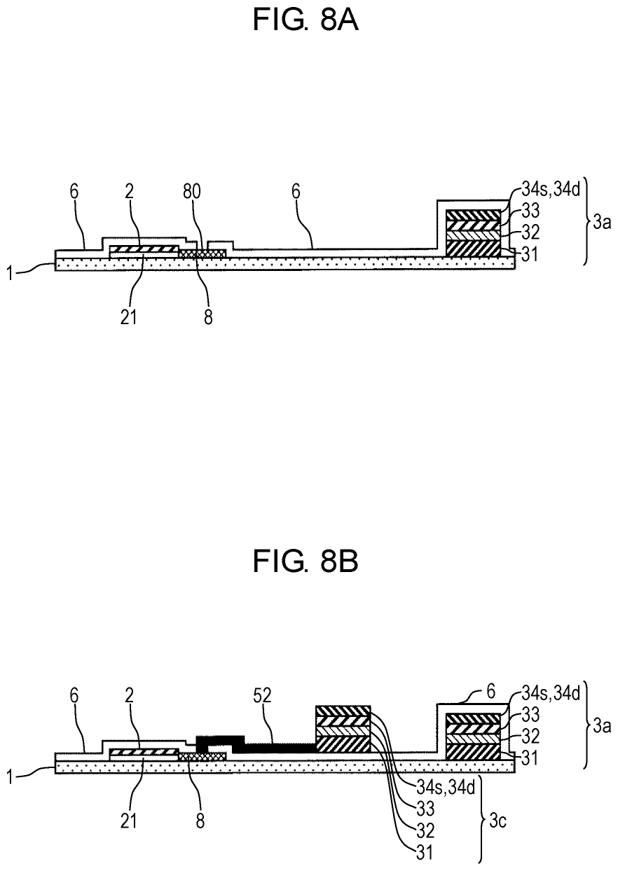

The wireless communication device according to Embodiment b2 is identical to the wireless communication device according to the above-described Embodiment A except for the following items (b2-1) to (b2-3) (see FIGS. 8A and 8B).

(b2-1) The wireless communication device according to the present embodiment requires protection layer 6 on circuit board 1 on the side where semiconductor chip 2 and the like are formed.
(b2-2) The wireless communication device of the present embodiment includes one or more “connected TFTs” as TFT 3. A connected TFT is a TFT that is electrically connected to semiconductor chip 2 by a wiring formed below protection layer 6 (that is, between circuit board 1 and protection layer 6), and is denoted by the reference numerals, “3a” in FIGS. 8A and 8B. In these drawings, TFT 3a does not appear to be electrically connected to semiconductor chip 2, but the wiring is omitted in consideration of the complexity of the wiring formed below protection layer 6 (that is, between circuit board 1 and protection layer 6). Actually, TFT 3a is directly or indirectly and electrically connected to semiconductor chip 2 by a wiring formed below protection layer 6 (that is, between circuit board 1 and protection layer 6). In the present embodiment, connected TFT 3a is below under protection layer 6 (that is, between circuit board 1 and protection layer 6) as illustrated in FIGS. 8A and 8B.
(b2-3) In the wireless communication device of the present embodiment, as illustrated in FIG. 8A, semiconductor chip 2 includes terminals 8. Terminal 8 is an exposed terminal having exposed surface 80 that is at least partially exposed from protection layer 6. Terminal 8 is connected to a desired portion of semiconductor chip 2. The number of terminals 8 is not particularly limited and may be one or more per one semiconductor chip 2, for example. Exposed surface 80 may be easily formed by masking at least a part of the surface of terminal 8 when protection layer 6 is formed. That is, a window formed in protection layer 6 allows at least a part of the surface of terminal 8 to be exposed from the window.

In the wireless communication device of the present embodiment, in addition to semiconductor chip 2 including terminal 8 instead of including terminal 8 having exposed surface 80 that is at least partially exposed from protection layer 6, TFT 3a may include an exposed terminal having an exposed surface that is at least partially exposed from the protection layer. The exposed terminal is connected to a desired portion of TFT 3a. The number of the exposed terminals is not particularly limited and may be, for example, one or more per one TFT 3a. The exposed surface of the exposed terminal may be formed by the same method as exposed surface 80 of terminal 8.

As a material for terminal 8, a metal having high conductivity is preferable, and for example, metal materials, such as silver (Ag), copper (Cu), nickel (Ni), aluminum (Al), and stainless steel (SUS), may be used. Terminal 8 is preferably a silver terminal from the viewpoint of simplicity of a reduction reaction described later. Terminal 8 is preferably a printed component from the viewpoints of further reducing the manufacturing cost, further improving the security performance with a simple structure, and further improving the simplicity of manufacturing the wiring.

In the wireless communication device of the present embodiment, as illustrated in FIG. 8B, connected TFT 3c electrically connected to semiconductor chip 2 and/or TFT 3a may be additionally formed at exposed surface 80 exposed from protection layer 6 at terminal 8. In FIG. 8B, connected TFT 3c that is electrically connected to semiconductor chip 2 at exposed surface 80 of terminal 8 that is exposed from protection layer 6 is additionally formed. The term “additionally formed” herein means that additional formation is performed after the manufacture of the wireless communication device is once completed. Preferably, after the manufacture of the wireless communication device is completed once, additional formation is possible in various scenes during use (utilization). Additional TFT 3c may be formed on protection layer 6, as illustrated in FIG. 8B, or may be formed on circuit board 1 by peeling off protection layer 6. When additional TFT 3c is formed on protection layer 6, as illustrated in FIG. 8B, additional TFT 3c may be electrically connected to semiconductor chip 2 and/or TFT 3a by wiring 52 formed on protection layer 6. When additional TFT 3c is formed on circuit board 1, additional TFT 3c may be electrically connected to semiconductor chip 2 and/or TFT 3a, that is, at least one of semiconductor chip 2 and TFT 3a by wiring 52 formed on protection layer 6 and/or a wiring formed below protection layer 6 (that is, between circuit board 1 and protection layer 6), that is, at least one of wiring 52 and the wiring formed under protection layer 6. In the wireless communication device according to the present embodiment, substantial addition of TFTs (particularity, memory unit ME (preferably ROM)) is achieved even after completion of manufacture by simply forming additional TFT 3c electrically connected to semiconductor chip 2 and/or TFT 3a, wiring 52 formed on protection layer 6, and a wiring formed below protection layer 6 (that is, between circuit board 1 and protection layer 6) as desired by a simple method such as a printing method (particularity, ink jet printing method), in various scenes. As a result, even if a different unique ID is assigned to each of the wireless communication devices, as compared to silicon-based wireless communication devices, it is possible to not only further sufficiently reduce the manufacturing cost per device, but also prevent the reduction in the operation speed and reliability, and more sufficiently prevent security-related problems, such as fake and forgery, with a simpler structure. In particular, in the wireless communication device according to the present embodiment, since the TFT (particularly, memory unit ME (preferably, ROM)) may be added, and the information (particularly, the unique ID) is not rewritten, it is possible to more sufficiently prevent security-related problems such as fake and forgery.

Terminal 8 may include a metal oxide layer on exposed surface 80 exposed from protection layer 6, similarly to terminal 7 described above. Terminal 8 is preferably a silver terminal, like terminal 7.

As illustrated in FIGS. 8A and 8B, one end of wiring 52 is electrically connected to additional TFT 3c and the other end is electrically connected to terminal 8 having exposed surface 80 that is partially exposed from protection layer 6. An object to be connected with the other end of wiring 52 is not limited to terminal 8, and may be, for example, a wiring electrically connected to semiconductor chip 2, and may be a wiring having exposed surface 80 that is at least partially exposed from protection layer 6, or may be an antenna having an exposed surface that is partially exposed from protection layer 6.

Wiring 52 is preferably a printed component from the viewpoints of further reducing the manufacturing cost, further improving the security performance with a simple structure, and further improving the simplicity of manufacturing the wiring. Wiring 52 being a printed component means that wiring 52 is a component manufactured by a printing method.

The thickness of wiring 52 may be determined within the same range as the thickness of wiring 5.

Wiring 52 is not particularly limited as long as the wiring is made of conductive material, and may be made of, for example, metal material, such as silver (Ag), copper (Cu), nickel (Ni), aluminum (Al), or stainless steel (SUS).

The wireless communication device according to the present embodiment can be manufactured by the same method as the method for manufacturing the wireless communication device according to Embodiment A, except that terminal 8 is formed and exposed surface 80 is formed on at least a part of the surface of terminal 8.

The wireless communication device according to the present embodiment may include an additional protection layer on additional TFT 3c and wiring 52. The additional protection layer may be selected from the same range as protection layer 6 described above. The additional protection layer may be formed by a method by which protection layer 6 can be formed.

### Wireless Communication Device According to Embodiment C

The wireless communication device according to Embodiment C of the present disclosure is a wireless communication device particularly useful for protecting privacy in the wireless communication device according to the above-described Embodiment A or Embodiment B.

The wireless communication device according to the present embodiment is identical to the wireless communication device according to the above-described Embodiment A or Embodiment B, except for the following items.

In a wireless communication device (for example, an RFID tag), when power is supplied from external reader device 101, the wireless communication device returns the unique ID stored therein and/or additional information to be stored (hereinafter, may be simply referred to as “information”) that can be linked to the unique ID according to the specification the device. Therefore, a receiver of the same standard would obtain information of any wireless communication device (for example, an RFID tag). Therefore, information (for example, a unique ID) stored in the wireless communication device (particularly, memory unit ME) is encrypted for privacy protection. That is, the wireless communication device (particularly, memory unit ME) stores the encrypted information. Further, the wireless communication device includes a key for decrypting the encrypted information. For example, the wireless communication device may have the key by printing on any area of the wireless communication device (for example, the back surface or the front surface of the circuit board). Decryption is to return the encrypted information back to plaintext. A key is required for decryption. For example, the key may be printed as a character string, a barcode, or a two-dimensional code, read by a camera of external reader device 101, and input to external reader device 101. If external reader device 101 is external reader device 101 that has a key for decryption, external reader device 101 may obtain the decrypted information. Once the above-described setting, that is, storage of the key, is performed, external reader device 101 reads the information as the same manner as a wireless communication device without encryption. In the case that external reader device 101 does not have a key for decryption, since external reader device 101 can only obtain unencrypted information, external reader device 101 cannot obtain the decrypted information, and as a result, privacy is protected. That is, in the case that the key is input to external reader device 101, external reader device 101 can decrypt the encrypted information. In the case that the key is not input to external reader device 101, external reader device 101 cannot decrypt the encrypted information.

### INDUSTRIAL APPLICABILITY

A wireless communication device according to the present disclosure includes a so-called RFID tag, an IC tag, and the like and is extremely useful for distribution management (logistics management), production management, inventory management, location management, history management, and the like in the retail industry such as convenience stores and supermarkets, the apparel industry, the transportation industry, and the publishing industry (libraries).

### REFERENCE MARKS IN THE DRAWINGS

1 circuit board
2 semiconductor chip
21 adhesive
3 TFT
3a connected TFT
3b non-connected TFT
31 gate electrode
32 insulating layer
33 semiconductor layer
34s source electrode
34d drain electrode
4 antenna
5 wiring
6 protection layer
7 exposed terminal
70 exposed surface
10 wireless communication device

1. A wireless communication semiconductor device comprising:
a circuit board;
a semiconductor chip mounted on the circuit board;
a thin film transistor provided on the circuit board; and
an antenna provided on the circuit board.

2. The wireless communication semiconductor device of claim 1, wherein an operation frequency of the semiconductor chip is higher than an operation frequency of the thin film transistor.

3. The wireless communication semiconductor device of claim 1, wherein the semiconductor chip is a silicon chip.

4. The wireless communication semiconductor device of claim 1, wherein the thin film transistor is an organic thin film transistor.

5. The wireless communication semiconductor device of claim 4, wherein the organic thin film transistor is a printed component.

6. The wireless communication semiconductor device of claim 1, further comprising:
a radio circuit unit configured to process a reception wave signal received by the antenna so as to generate a reception signal and to generate a transmission wave signal to be transmitted by the antenna; and
a memory unit configured to store unique ID-related information related to a unique ID and at least one of the reception signal and the transmission signal, wherein
the radio circuit unit is provided on the semiconductor chip, and
at least a part of the memory unit is provided in the thin film transistor.

7. The wireless communication semiconductor device of claim 6, wherein
the memory unit includes:
a unique ID memory unit configured to store the unique ID; and
another memory unit configured to store information other than the unique ID, wherein
the unique ID memory unit is provided in the thin film transistor, and
the another memory unit is provided in the semiconductor chip or the thin film transistor.

8. The wireless communication semiconductor device of claim 6, further comprising
a protection layer, wherein
the circuit board includes a formation surface having the semiconductor chip and the thin film transistor formed thereon,
the protection layer covers the semiconductor chip, the thin film transistor, and the formation surface of the circuit board,
the thin film transistor includes:
a connected thin film transistor electrically connected to the semiconductor chip by a wiring between the protection layer and the circuit board; and
a non-connected thin film transistor that is not electrically connected to the semiconductor chip by any wiring between the protection layer and the circuit board, and
the non-connected thin film transistor or the semiconductor chip includes an exposed terminal having an exposed surface exposed from the protection layer.

9. The wireless communication semiconductor device of claim 8, wherein
in a case that the non-connected thin film transistor includes the exposed terminal, the non-connected thin film transistor is electrically connectable to the semiconductor chip by a wiring provided on the protection layer on the exposed surface of the exposed terminal, and
in a case that the semiconductor chip includes the exposed terminal, the semiconductor chip is electrically connectable to the non-connected thin film transistor by a wiring provided on the protection layer on the exposed surface of the exposed terminal.

10. The wireless communication semiconductor device of claim 6, further comprising
a protection layer, wherein
the circuit board includes a formation surface having the semiconductor chip and the thin film transistor formed thereon,
the protection layer covers the semiconductor chip, the thin film transistor, and the formation surface of the circuit board,
the thin film transistor includes a connected thin film transistor electrically connected to the semiconductor chip by a wiring below the protection layer, the connected thin film transistor being located between the protection layer and the circuit board, and
at least one of the semiconductor chip and the connected thin film transistor includes an exposed terminal having an exposed surface exposed from the protection layer.

11. The wireless communication semiconductor device of claim 10, wherein a thin film transistor electrically connected to the at least one of the semiconductor chip and the connected thin film transistor on the exposed surface of the exposed terminal is able to be additionally formed.

12. The wireless communication semiconductor device of claim 10, wherein the exposed terminal includes a metal oxide layer provided on the exposed surface.

13. The wireless communication semiconductor device of claim 10, wherein the exposed terminal is a silver terminal.

14. The wireless communication semiconductor device of claim 6, further comprising:
a power supply circuit unit configured to generate driving power to drive the wireless communication semiconductor device; and
a control circuit unit configured to
cause the memory unit to store the unique ID-related information and the at least one of the reception signal and the transmission signal, and
cause the radio circuit unit to generate the reception signal and the transmission signal, wherein
the power supply circuit unit is provided on the semiconductor chip, and
the control circuit unit is provided in the semiconductor chip or the thin film transistor.

15. The wireless communication semiconductor device of claim 14, wherein the control circuit unit includes:
a memory control circuit unit configures to cause the memory unit to store the unique ID-related information and the at least one of the reception signal and the transmission signal, and
another control circuit unit configured to cause the radio circuit unit to generate the reception signal and the transmission signal, and
the memory control circuit unit and the another control circuit unit are independently provided in the semiconductor chip or the thin film transistor.

16. The wireless communication semiconductor device of claim 6, wherein the wireless communication semiconductor device is configured to receive driving power from an external reader device and to return unique ID-related information stored in the memory unit to the external reader device.

17. The wireless communication semiconductor device of claim 6, further comprising a key, wherein
the wireless communication semiconductor device is configured to store encrypted information including the unique ID-related information, and
the key is for decrypting the encrypted information.

18. The wireless communication semiconductor device of claim 17, wherein
the key is able to be input to an external reader device,
in a case that the key is input to an external reader device, the external reader device is able to decrypt the encrypted information, and
in a case that the key is not input to the external reader device, the external reader device is not able to decrypt the encrypted information.

19. A method for manufacturing a wireless communication semiconductor device, comprising:
mounting a semiconductor chip on a circuit board; and
forming a thin film transistor, an antenna, and a wiring on the circuit board by printing.

20. The method of claim 19, wherein
the wireless communication semiconductor device configured to store encrypted information,
the method further comprising forming a key for decrypting the encrypted information in the wireless communication semiconductor device by printing.

21. The wireless communication semiconductor device of claim 8, wherein the exposed terminal includes a metal oxide layer provided on the exposed surface.

22. The wireless communication semiconductor device of claim 8, wherein the exposed terminal is a silver terminal.
